(19) United States
(12) Patent Application Publication
(10) Pub. No.: US 2016/0133566 A1
(43) Pub. Date: May 12, 2016

(54) MULTI-LAYER TRANSMISSION LINE STRUCTURE FOR MISALIGNMENT RELIEF

(71) Applicant: Morfis Semiconductor, Inc., Irvine, CA (US)

(72) Inventor: Haitao Li, Irvine, CA (US)

(21) Appl. No.: 14/930,532

(22) Filed: Nov. 2, 2015

Related U.S. Application Data
(60) Provisional application No. 62/076,419, filed on Nov. 6, 2014.

(51) Int. Cl. H01L 23/522; H01L 23/66; H01L 23/528

(52) U.S. Cl. CPC H01L 23/5227; H01L 23/5283; H01L 23/66

(57) ABSTRACT

A circuit includes a dielectric layer and a stacked inductor. A first metal line is disposed on a first side of the dielectric layer. A second metal line is disposed on a second side of the dielectric layer and inductively coupled with the first metal line through a portion of the dielectric layer. The first metal line has a first width between respective edges of the first metal line. The second metal line has a second width between respective edges of the second metal line. The second width of the second metal line is greater than the first width of the first metal line. The first metal line is vertically aligned with the second metal line. The respective edges of the second metal line are located outwardly of the respective edges of the first metal line.

### CROSS-REFERENCE TO RELATED APPLICATIONS

This application relates to and claims the benefit of U.S. Provisional Application No. 62/076,419, filed Nov. 6, 2014 and entitled “MULTI-LAYER TRANSMISSION LINE STRUCTURE FOR MISALIGNMENT RELIEF,” the entirety of the disclosure of which is wholly incorporated by reference herein.

### STATEMENT RE: FEDERALLY SPONSORED RESEARCH/DEVELOPMENT

Not Applicable

### BACKGROUND

1. Technical Field

The present disclosure generally relates to the field of electronics. More particularly, the present disclosure relates to a multi-layer structure including inductively-coupled transmission lines.

2. Related Art

A typical printed circuit board (PCB) includes one or more layers of insulating material upon which patterns of electrical conductors are formed. PCBs are generally used to mechanically support and electrically connect electronic components using electrically-conductive pathways or traces that conduct signals on the PCB. PCBs may be generally classified into single-sided PCBs, double-sided PCBs and multi-layer PCBs according to the number of circuit pattern surfaces.

Electronic devices and complex electronic systems require highly reliable interconnects and electronic components. A transmission line is an interconnect used to guide electromagnetic wave or electrical energy from one point to another with the intention of least possible loss and distortion. The terms “transmission line” or “interconnect” include a variety of technologies that provide a path for conduction or propagation of electrical or electromagnetic signals.

A transmission line can be formed to define an integrated circuit, such as a trace on a single-layer or multi-layer substrate. For example, passive elements in circuits employ transmission lines in different configurations to achieve the desired functionality and to meet performance specifications. A transmission line circuit can be modularized to form a basic functional building block element of a larger device, network, subsystem, or system. Transmission lines are extensively used in the design of radio-frequency (RF) circuits and RF PCBs. PCBs for circuits that support transmission of signals with the wavelengths of RF and microwave frequencies must do so with minimal loss and stable, consistent performance.

Microstrip is a type of transmission line technology consisting of a flat metal conductor strip attached to one side of a flat dielectric substrate and a single ground-plane conductor covering the other side of the dielectric. Stripline is a type of transmission line technology having a flat metal conductor strip sandwiched between two dielectric substrates whose outer surfaces are covered with ground-plane conductors.

Transmission lines on different layers of a PCB have been designed to overlay and align vertically with respect to one another to produce mutual inductive coupling. Mutual inductance occurs when the change in current in one inductor induces a voltage in another nearby inductor. Mutual inductance is important as the mechanism by which transformers, filters, couplers, spiral inductors, and other passive components work. In RF and fast switching circuits the inductance and capacitance of the PCB conductors can be used as a deliberate part of the circuit design, obviating the need for additional discrete components. For example, in an RF front-end circuit in a communication system, the coupling mechanism between inductors is an important component of the filter design. In the planar circuits, for example, in an environment of microstrip or stripline, the mutual coupling can be achieved in a variety of ways.

Circuits having mutually coupled transmission lines are widely used. For example, on-chip inductors are used in semiconductor structures for analog applications. On-chip inductors are often employed with other semiconductor components to form a resonant circuit having a high quality factor or Q factor. Values for the Q factor can be used in defining the performance of an inductor or tuned circuit.

Manufacturing processes have many factors that affect their success, and in each, the possibility of variation is introduced. For example, several aspects of the PCB manufacturing processes may subject PCB components to strain or stress (e.g., mechanical, thermal, physical, chemical, and the like). Transmission lines may be fabricated in misalignment with respect to each other for a variety of reasons, e.g., line width variation due to the photolithography process.

There is a continuing need in the art for improved methods for fabricating coupled transmission lines for forming inductively structures.

### BRIEF SUMMARY

The present disclosure is directed to circuits including coupled transmission lines and methods for configuring and fabricating transmission lines. Various types of planar configurations are contemplated including microstrip, stripline, finline and coplanar structures, but the presently-disclosed approach can be extended to any form of coupled lines. The presently-disclosed techniques allow for the use of standard printed circuit board (PCB) technologies for integrated circuits manufacturing.

According to an aspect of the present disclosure, there is a circuit. The circuit includes a dielectric layer and a stacked inductor. A first metal line is disposed on a first side of the dielectric layer. A second metal line is disposed on a second side of the dielectric layer and inductively coupled with the first metal line through a portion of the dielectric layer. The first metal line has a first width between respective edges of the first metal line. The second metal line has a second width between respective edges of the second metal line. The second width of the second metal line is greater than the first width of the first metal line. The first metal line is vertically aligned with the second metal line. The respective edges of the second metal line are located outwardly of the respective edges of the first metal line

According to another aspect of the present disclosure, there is a stacked inductor device. The stacked inductor device includes a first inductor element and a second inductor element. The first inductor element includes a plurality of segments. Each of the plurality of segments of the first inductor element has a first width. The second inductor element includes a plurality of segments. Each of the plurality of segments of the second inductor element has a second width The second inductor element is stacked upon the first inductor element. At least one dielectric layer is disposed between the first inductor element and the second inductor element The second inductor element is inductively coupled with the first inductor element through a portion of the dielectric layer. The respective edges of the plurality of segments of the second inductor element are located outwardly of the respective edges of the plurality of segments of the first inductor element.

### BRIEF DESCRIPTION OF THE DRAWINGS

Objects and features of the presently-disclosed transmission line structures will become apparent to those of ordinary skill in the art when descriptions of various embodiments thereof are read with reference to the accompanying drawings, of which:

FIG. 1A is a cross-sectional view showing a printed circuit board in accordance with an embodiment of the present disclosure;

FIG. 1B is a plan view of the embodiment of the printed circuit board of FIG. 1A with a signal layer (upper or lower) shown in phantom lines;

FIG. 2A is a plan view showing a conventional structure of two inductors overlapped with each other;

FIG. 2B is a plan view showing the two inductors of FIG. 2A partially overlapped with each other;

FIG. 3A is a plan view showing a structure of two inductors overlapped with each other in a first configuration in accordance with an embodiment of the present disclosure;

FIG. 3B is a plan view showing the two inductors of FIG. 3A overlapped with each other in a second configuration in accordance with an embodiment of the present disclosure;

FIG. 4A is a plot illustrating inductance variation for the structure shown in FIGS. 3A and 3B in accordance with an embodiment of the present disclosure;

FIG. 4B is a plot illustrating inductance variation for the structure 200 shown in FIGS. 2A and 2B in accordance with an embodiment of the present disclosure;

FIG. 5A is a plot illustrating a portion of the plot shown in FIG. 4A;

FIG. 5B is a plot illustrating a portion of the plot shown in FIG. 4B;

FIG. 6 is a cross-sectional view showing a three-layer transmission line in accordance with an embodiment of the present disclosure;

FIG. 7 is a cross-sectional view showing a four-layer transmission line in accordance with an embodiment of the present disclosure; and

FIG. 8 is a cross-sectional view showing a five-layer transmission line in accordance with an embodiment of the present disclosure.

### DETAILED DESCRIPTION

Hereinafter, embodiments of mutually coupled transmission lines are described with reference to the accompanying drawings. Like reference numerals may refer to similar or identical elements throughout the description of the figures.

This description may use the phrases “in an embodiment,” “in embodiments,” “in some embodiments,” or “in other embodiments,” which may each refer to one or more of the same or different embodiments in accordance with the present disclosure.

As it is used in this description, “printed circuit board” (or “PCB”) generally refers to any and all systems that provide, among other things, mechanical support to electrical components, electrical connection to and between these electrical components, combinations thereof, and the like. The PCBs described herein may include electrical components. The “PCBs” and “circuit boards” described herein are not limited to electrical component-populated boards, but also include non-populated circuit traced substrates of all types, e.g., semiconductor integrated circuits, etc.

Various embodiments of the present disclosure provide a method of fabricating inductors. The presently-disclosed methods for fabricating inductors may be used in integrated circuits and other semiconductor devices and particularly in radio frequency (RF) circuits. Various embodiments of the present disclosure provide a multi-layer structure including inductively-coupled transmission lines having an overlapped width that is optimized to obtain a stacked inductor having desired electrical characteristics. It is to be understood that features of the presently-disclosed multi-layer structure embodiments may be combined in a variety of configurations. Embodiments of the presently-disclosed multi-layer structure may be suitable for use with a variety of circuits.

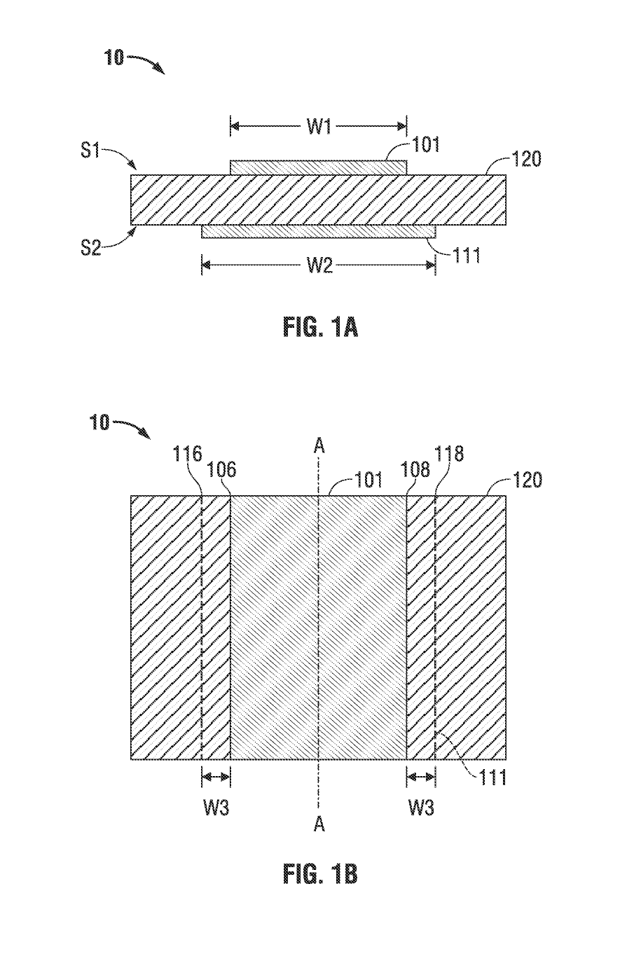

Referring now to FIGS. 1A and 1B, there is shown a portion of a printed circuit board in accordance with an embodiment of the present disclosure. The printed circuit board (shown generally as 10 in FIGS. 1A and 1B) includes a substrate 120 having a first side “S1” (e.g., an upper side) and a second side “S2” (e.g., a lower side). The substrate 120 may be formed of any suitable dielectric material by any suitable process. In some embodiments, the dielectric material may be air. A first transmission line 101 is disposed on the first side “S1” of the dielectric layer 120. The first transmission line 101 has a first width “W1” between its respective edges 106 and 108. A second transmission line 111 is disposed on the second side “S2” of the dielectric layer 120. The second transmission line 111 has a second width “W2” between its respective edges 116 and 118. In the embodiment shown in FIGS. 1A and 1B, the second width “W2” is greater than the first width “W1.” The first and second transmission lines 101 and 111 may include any suitable electrically-conductive material, e.g., a metal. In some embodiments, the first and second transmission lines 101 and 111 may include copper, gold, silver, or other conductive metals or metal alloys having similar conductivity values.

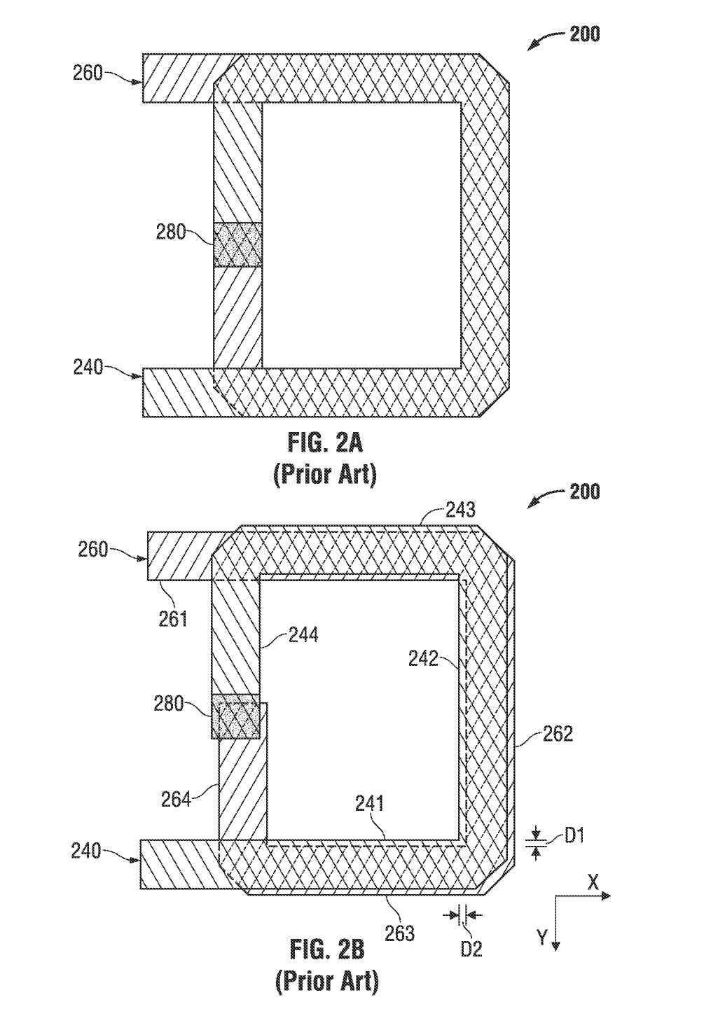

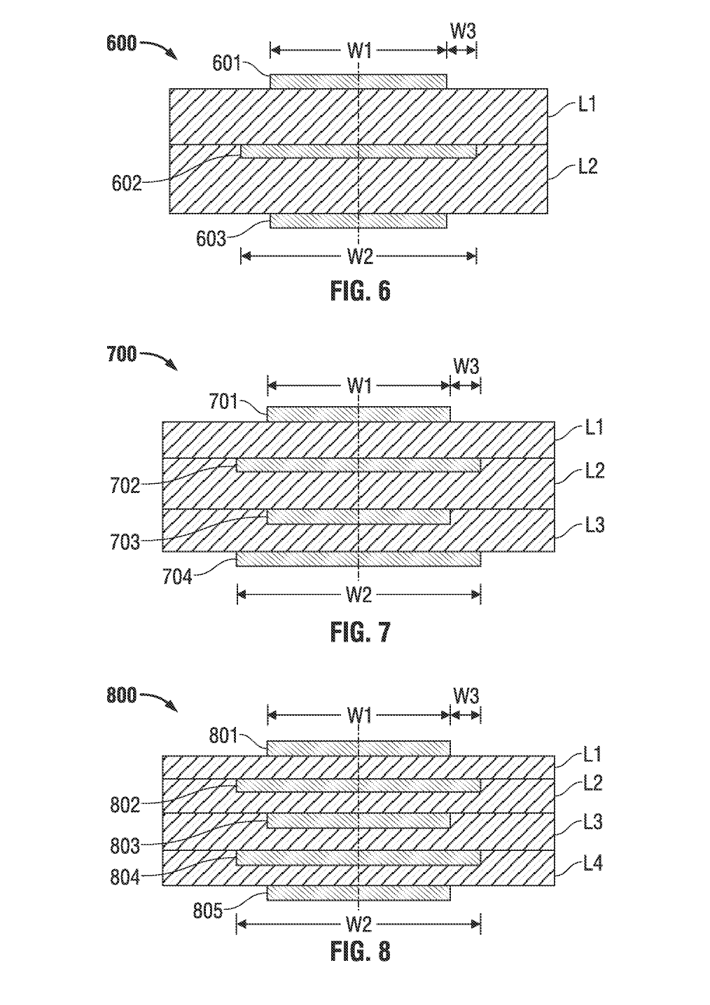

In some embodiments, as shown for example in FIG. 1B, when the first transmission line 101 and the second transmission line 111 are aligned along their central longitudinal axis “A-A”, the second transmission line 111 overlaps the first transmission line 101, whereby the edges 116 and 118 of the second transmission line 111 overlap the edges 106 and 108 of the first transmission line 101, respectively, by width “W3.” In some embodiments, width “W3” may be 15 microns. In the preferred embodiment, width “W3” is 10% of the first width “W1,” which may accommodate many process variations that might otherwise result in transmission line misalignment and reduction in the magnitude of inductance in the lines. When proper alignment of transmission lines is achieved, an inductor having high inductance can be obtained. It is to be understood that printed circuit board 10 may include any of the elements of structure 300 shown in FIGS. 2A and 2B, structure 600 shown in FIG. 6, structure 700 shown in FIG. 7, and/or structure 800 shown in FIG. 8.

FIGS. 2A and 2B show a conventional structure 200 including a first inductor 240, a second inductor 260, and a via 280. In FIG. 2A, the second inductor 260 is shown in vertical alignment with the first inductor 240. FIG. 2B shows the second inductor 260 in misalignment with the first inductor 240, e.g., as a result of process variation. In FIGS. 2A and 2B, the dielectric layer between the first and second inductors 240 and 260 is omitted for ease of illustration and clarity.

The first inductor 240 includes a first segment 241, a second segment 242, a third segment 243 and a fourth segment 244. The second inductor 260 includes a first segment 261, a second segment 262, a third segment 263 and a fourth segment 264. The via 280 is connected to the fourth segment 244 of the first inductor 240 and the fourth segment 264 of the second inductor 260.

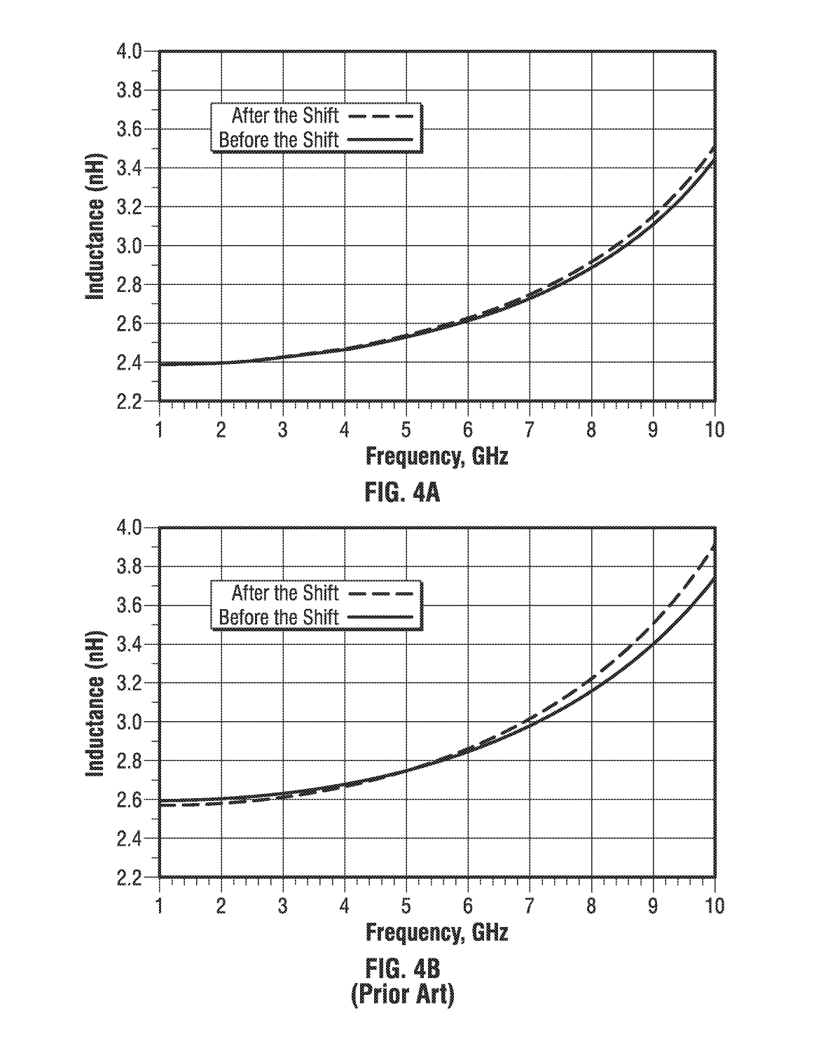

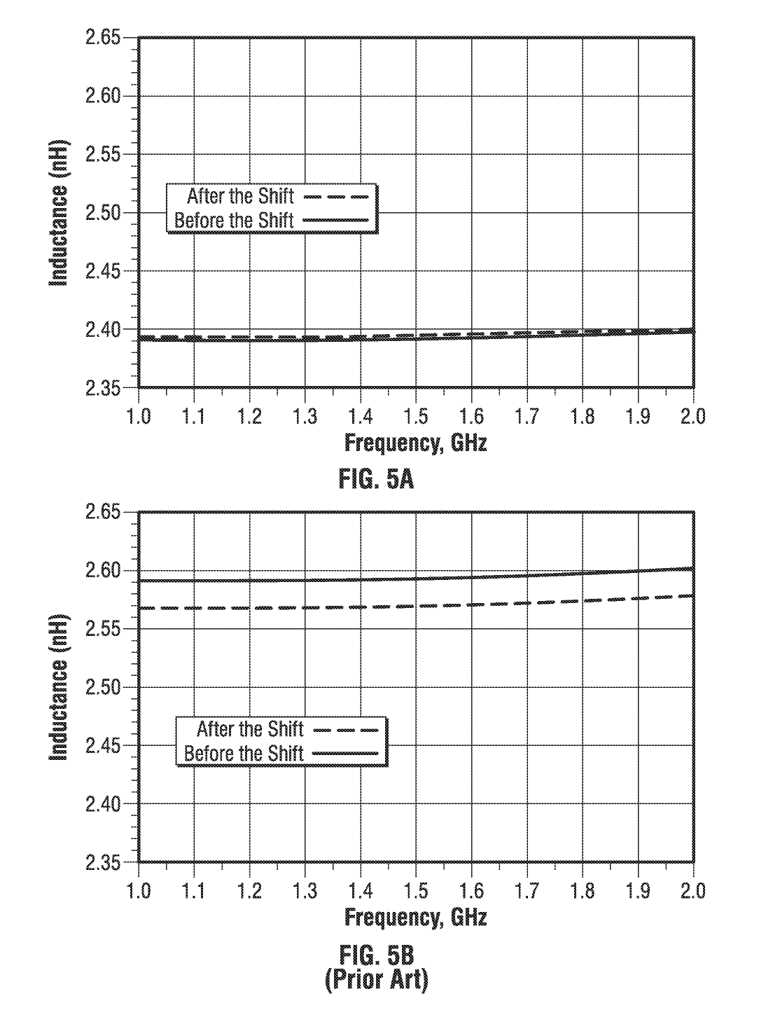

In FIG. 2B, the first and second inductors 240 and 260 are offset or shifted with respect to each other. As depicted in FIG. 2B, the first, second, third and fourth segments 261, 262, 263 and 264 of the second inductor 260 are shifted in relation to the first, second, third and fourth segments 241, 242, 243 and 244 of the first inductor 240, respectively, by a distance “D1” (along the direction indicated by arrow Y) and shifted by a distance “D2” (along the direction indicated by arrow X). As described later in this disclosure with respect to FIGS. 4B and 5B, the magnitude of inductance in the lines changes with the “shift.”

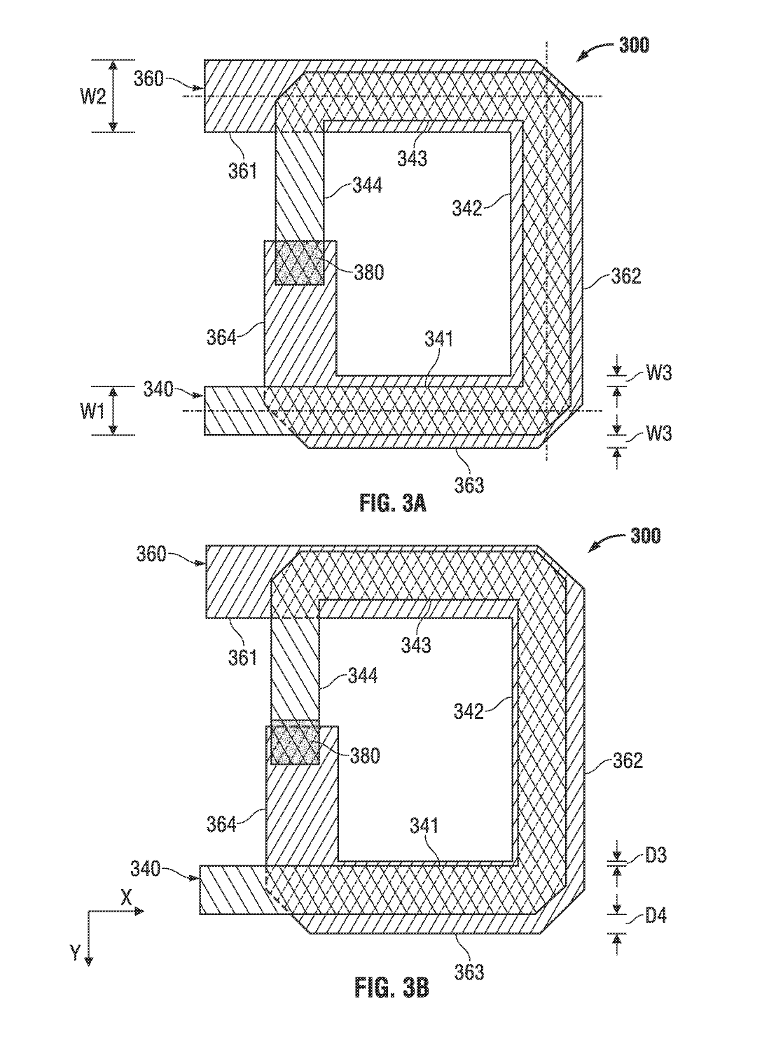

FIG. 3A shows a structure 300 including a first inductor 340 and a second inductor 360 overlapped with each other in a first configuration in accordance with an embodiment of the present disclosure. In FIG. 3B, the first and second inductors 340 and 360 are overlapped with each other in a second configuration in accordance with an embodiment of the present disclosure. In FIGS. 3A and 3B, the dielectric layer between the first and second inductors 340 and 360 is omitted for ease of illustration and clarity.

The first inductor 340 has a first width “W1.” The second inductor 360 has a second width “W2.” The first and second inductors 340 and 360 each include a plurality of portions or segments. In FIGS. 3A and 3B, the first inductor 340 includes a first segment 341, a second segment 342, a third segment 343 and a fourth segment 344, and the second inductor 360 includes a first segment 361, a second segment 362, a third segment 363 and a fourth segment 364. In some embodiments, the fourth segment 344 of the first inductor 340 and the fourth segment 364 of the second inductor 360 are electrically coupled to a via 380. It is to be understood that the first inductor 340 and the second inductor 360 may include any number of portions or segments. The first inductor 340 and the second inductor 360 may include straight line segments, curvilinear line segments, angular line segments, etc.

In the illustrative embodiment shown in FIGS. 3A and 3B, the first inductor 340 has a substantially rectilinear shape that is partially defined by the first segment 341 and the third segment 343, which are arranged in parallel and spaced apart from each other, and partially defined by the second segment 342 and the fourth segment 364, which are arranged in parallel and spaced apart from each other (and arranged perpendicular to the first segment 341 and the third segment 343). In FIGS. 3A and 3B, the second inductor 360 has a substantially rectilinear shape, e.g., similar to the first inductor 340. It is to be understood that the first inductor 340 and/or the second inductor 360 may be an element of a more complex pattern, e.g., a spiral or meander planar coil.

As illustratively depicted in FIG. 3A, when the center line of each of the first segment 341, the second segment 342 and the third segment 343 of the first inductor 340 is aligned with the center line of each of the first segment 361, the second segment 361 and the third segment 363 of the second inductor 360, respectively, the first, second, and third segments 361, 362 and 363 of the second inductor 360 overlap the first, second, and third segments 341, 342 and 343 of the first inductor 340, respectively, by width “W3.” In the preferred embodiment, width “W3” is 10% of the first width “W1,” which may accommodate many process variations that might otherwise result in transmission line misalignment and adversely affect the magnitude of inductance in the lines.

In FIG. 3B, the first and second inductors 340 and 360 are shifted with respect to each other. As depicted in FIG. 3B, the first, second, third and fourth segments 361, 362, 363 and 364 of the second inductor 360 are shifted in relation to the first, second, third and fourth segments 341, 342, 343 and 344 of the first inductor 340, respectively, by a distance “D3” (along the direction indicated by arrow Y) and shifted by a distance “D4” (along the direction indicated by arrow X).

FIG. 4A shows a plot of frequency (GHz) versus inductance (nH) for the structure 300 shown in FIGS. 3A and 3B. FIG. 5A shows a portion (“zoom in view”) of the plot of FIG. 4A for the frequency range of 1.0 GHz to 2.0 GHz. In FIGS. 4A and 5A, the solid line represents the first configuration of the structure 300 (i.e., “before the shift”) shown in FIG. 3A, and the dashed line represents the second configuration of the structure 300 (i.e., “after the shift”) shown in FIG. 3B. In the example “shift” depicted in FIG. 3B, the distances “D3” and “D4” are taken to be 15 micrometers each.

In FIG. 4B, a plot of frequency (GHz) versus inductance (nH) is shown for the conventional structure 200 shown in FIG. 2A. FIG. 5B shows a portion (“zoom in view”) of the plot of FIG. 4B for the frequency range of 1.0 GHz to 2.0 GHz. In FIGS. 4B and 5B, the solid line represents the structure 200 “before the shift” shown in FIG. 2A, and the dashed line represents the structure 200 “after the shift” shown in FIG. 2B. In the example “shift” depicted in FIG. 2B, the distances “D1” and “D2” are taken to be 15 micrometers each.

As seen in the plot of FIG. 4A, there is less inductance variation from the shift, particularly above 6 GHz, as compared to the plot of FIG. 4B.

FIG. 6 shows a structure 600 including three transmission lines in accordance with an embodiment of the present disclosure. The structure 600 includes a first transmission line 601 having a first width “W1,” a second transmission line 602 having a second width “W2,” and a third transmission line 603 having the first width “W1.” The first, second and third transmission lines 601, 602 and 603 are similar to the first and second transmission lines 101 and 111 shown in FIG. 1, and further description thereof is omitted in the interest of brevity.

The structure 600 includes a first insulating layer L1 and a second insulating layer L2. The first and second insulating layers L1 and L2 may be formed of any suitable dielectric material by any suitable process. The size and shape of the first and second insulating layers L1 and L2 may be varied from the configuration depicted in FIG. 6.

In the illustrative embodiment shown in FIG. 6, the first transmission line 601 is disposed on the first insulating layer L1, the second transmission line 602 is embedded in the second insulating layer L2, and the third transmission line 603 is disposed on the second insulating layer L2. It is to be understood that any of the first, second and third transmission lines 601, 602 and 603 may be disposed on the surface of an insulating layer or embedded in an insulating layer. As depicted in FIG. 6, the first, second and third transmission lines 601, 602 and 603 are center line aligned with each other, and the second transmission line 602 overlaps the first and third transmission lines 601 and 603 by width “W3.” As previously mentioned above, in the preferred embodiment, width “W3” is 10% of the first width “W1,” which may accommodate many process variations that might otherwise result in transmission line misalignment and adversely affect the magnitude of inductance in the lines.

FIG. 7 shows a structure 700 including four transmission lines in accordance with an embodiment of the present disclosure. The structure 700 includes a first transmission line 701 having a first width “W1,” a second transmission line 702 having a second width “W2,” a third transmission line 703 having the first width “W1,” and a fourth transmission line 704 having the second width “W2.” The first, second, third and fourth transmission lines 701, 702, 703 and 704 are similar to the first and second transmission lines 101 and 111 shown in FIG. 1, and further description thereof is omitted in the interest of brevity.

The structure 700 includes a first insulating layer L1, a second insulating layer L2 and a third insulating layer L3. The first, second and third insulating layers L1, L2 and L3 may be formed of any suitable dielectric material by any suitable process. The size and shape of the first, second and third insulating layers L1, L2 and L3 may be varied from the configuration depicted in FIG. 7.

In the illustrative embodiment shown in FIG. 7, the first transmission line 701 is disposed on the first insulating layer L1, the second transmission line 702 is embedded in the second insulating layer L2, the third transmission line 703 is embedded in the third insulating layer L3, and the fourth transmission line 704 is disposed on the third insulating layer L3. It is to be understood that any of the first, second, third and fourth transmission lines 701, 702, 703 and 704 may be disposed on the surface of an insulating layer or embedded in an insulating layer. As depicted in FIG. 7, the first, second, third and fourth transmission lines 701, 702, 703 and 704 are center line aligned with each other, and the second and fourth transmission lines 702 and 704 overlap the first and third transmission lines 701 and 703 by width “W3.”

FIG. 8 shows a structure 800 including five transmission lines in accordance with an embodiment of the present disclosure. The structure 800 includes a first transmission line 801, a second transmission line 801, a third transmission line 803, a fourth transmission line 804, and a fifth transmission line 805. As seen in FIG. 8, the first, third and fifth transmission lines 801, 803 and 805 have a first width “W1,” and the second and fourth transmission lines 702 and 704 have a second width “W2.” The first, second, third, fourth and fifth transmission lines 801, 802, 803, 804 and 805 are similar to the first and second transmission lines 101 and 111 shown in FIG. 1, and further description thereof is omitted in the interest of brevity.

In the illustrative embodiment shown in FIG. 8, the first transmission line 801 is disposed on a first insulating layer L1, the second transmission line 802 is embedded in a second insulating layer L2, the third transmission line 803 is embedded in a third insulating layer L3, the fourth transmission line 804 is embedded in a fourth insulating layer L4, and the fifth transmission line 805 is disposed on the fourth insulating layer L4. It is to be understood that the first, second, third, fourth and fifth transmission lines 801, 802, 803, 804 and 805 may be disposed on the surface of an insulating layer or embedded in an insulating layer. As depicted in FIG. 8, the first, second, third, fourth and fifth transmission lines 801, 802, 803, 804 and 805 are center line aligned with each other, and the second and fourth transmission lines 802 and 804 overlap the first, third and fifth transmission lines 801, 803 and 805 by width “W3.”

Although embodiments have been described in detail with reference to the accompanying drawings for the purpose of illustration and description, it is to be understood that the disclosed processes and apparatus are not to be construed as limited thereby. It will be apparent to those of ordinary skill in the art that various modifications to the foregoing embodiments may be made without departing from the scope of the disclosure. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A circuit, comprising:
a dielectric layer; and
a stacked inductor, including:
a first metal line having a first width between respective edges of the first metal line, the first metal line disposed on a first side of the dielectric layer; and
a second metal line having a second width between respective edges of the second metal line, the second width greater than the first width, the second metal line disposed on a second side of the dielectric layer and inductively coupled with the first metal line through a portion of the dielectric layer,
wherein the first metal line is vertically aligned with the second metal line, and wherein the respective edges of the second metal line are located outwardly of the respective edges of the first metal line.

2. The circuit of claim 1, wherein the respective edges of the second metal line are located outwardly of the respective edges of the first metal line by a distance equal to ten percent of the first width.

3. The circuit of claim 1, wherein the first metal line includes a plurality of segments.

4. The circuit of claim 3, wherein the plurality of segments of the first metal line includes a first segment, a second segment, a third segment, and a fourth segment.

5. The circuit of claim 4, wherein the first segment and the third segment of the first metal line are arranged in parallel and spaced apart from each other, and wherein the second segment and the fourth segment of the first metal line are arranged in parallel and spaced apart from each other.

6. The circuit of claim 5, wherein the second metal line includes a first segment, a second segment, a third segment, and a fourth segment.

7. The circuit of claim 6, wherein the first segment and the third segment of the second metal line are arranged in parallel and spaced apart from each other, and wherein the second segment and the fourth segment of the second metal line are arranged in parallel and spaced apart from each other.

8. A stacked inductor device, comprising:
a first inductor element including a plurality of segments, each of the plurality of segments of the first inductor element having a first width;
a second inductor element including a plurality of segments, each of the plurality of segments of the second inductor element having a second width, wherein the second inductor element is stacked upon the first inductor element;
at least one dielectric layer disposed between the first inductor element and the second inductor element,
wherein the second inductor element is inductively coupled with the first inductor element through a portion of the dielectric layer, and
wherein respective edges of the plurality of segments of the second inductor element are located outwardly of respective edges of the plurality of segments of the first inductor element.

9. The stacked inductor device of claim 8, wherein the respective edges of the plurality of segments of the second inductor element are located outwardly of the respective edges of the plurality of segments of the first inductor element by a distance equal to ten percent of the first width.

10. The stacked inductor device of claim 8, wherein the plurality of segments of the first inductor element includes a first segment, a second segment, a third segment, and a fourth segment.

11. The stacked inductor device of claim 10, wherein the first segment and the third segment of the first inductor element are arranged in parallel and spaced apart from each other, and wherein the second segment and the fourth segment of the first inductor element are arranged in parallel and spaced apart from each other.

12. The stacked inductor device of claim 11, wherein the second metal line includes a first segment, a second segment, a third segment, and a fourth segment.

13. The stacked inductor device of claim 12, wherein the first segment and the third segment of the second inductor element are arranged in parallel and spaced apart from each other, and wherein the second segment and the fourth segment of the second inductor element are arranged in parallel and spaced apart from each other.

14. The stacked inductor device of claim 10, wherein the second segment and the fourth segment of the first inductor element are arranged perpendicular to the first segment and the third segment of the first inductor element.

15. The stacked inductor device of claim 8, wherein the first inductor element has a substantially rectilinear shape.

16. The stacked inductor device of claim 15, wherein the second inductor element has a substantially rectilinear shape.
